(19) United States
(12) Patent Application Publication
(10) Pub. No.: US 2007/0252238 A1
(43) Pub. Date: Nov. 1, 2007

(54) Tungstein plug as fuse for IC device

(76) Inventor: Charles Lin, Fremont, CA (US)

Correspondence Address: MURABITO, HAO & BARNES, LLP, TWO NORTH MARKET STREET, THIRD FLOOR, SAN JOSE, CA, 95113, US

(21) Appl. No.: 11/789,890

(22) Filed: Apr. 25, 2007

Related U.S. Application Data
(60) Provisional application No. 60/796,073, filed on Apr. 27, 2006.

(51) Int. Cl. H01L 29/00

(52) U.S. Cl. 257/529

(57) ABSTRACT

The present invention provides a fuse circuit in a dielectric layer for trimming an Integrated Circuit. The fuse circuit has a first conductive layer, a second conductive layer and a third conductive layer. A first metal plug is coupled between the first conductive layer and the second conductive layer. At least one metal plug is coupled between the first conductive layer and the third conductive layer. Consequently, a conductive path is formed between the second and third conductive layers via the first metal plug, the first conductive layer and the at least one metal plug. The conductive path can be cut off by applying a current to the first metal plug.

### RELATED U.S. APPLICATIONS

This application claims priority to co-pending provisional application Ser. No. 60/796,073, filed on Apr. 27, 2006, which is hereby incorporated by reference to this specification.

### FIELD OF THE INVENTION

The invention relates to integrated circuit (IC) design, and more specifically, to device trimming.

### BACKGROUND OF THE INVENTION

In integrated devices of various types, there are circuit elements of which a characteristic parameter, such as frequency, has to have a predetermined tolerance. However, a very low tolerance value is difficult to achieve because of accuracy limits inherent in the fabricating processes by which the integrated devices are produced.

This problem is generally solved by a subsequent trimming process of the circuit elements. There are a number of ways to perform device trimming, including the fuses or One-Time-Programmable (OTP) method, the use of memories such as EEPROM or Flash which allow for multiple read and write operations, and laser trimming. The OTP method includes, but is not limited to, metal fuse, poly fuse and Zener diode. The above-mentioned methods are capable of adjusting the characteristic parameter, such as frequency to be within the predetermined tolerance.

A fuse basically can be defined as a circuit element whose properties can be modified by various means after the manufacturing process to improve the overall performance of the IC.

Metal fuses, poly fuses and Zener diodes are devices that require the passing of a large amount of electrical energy therethrough to effect a permanent change in electrical resistivity in the device. The terminals of each fuse are accessible from outside the integrated device by means of a number of bonding pads. If a current of a sufficiently high value is supplied to the bonding pads, the fuse can be blown. In many instances such action is intended to trim, program or to burn the fuse. Usually, a separate sensing circuitry is needed for detecting the state of the fuse.

Poly and metal fuses (e.g., aluminum metal fuses) are commonly used fuses. They are easy to incorporate in the manufacturing process but may require additional masking step(s) to make. During burning, the large amount of energy applied can evaporate the fuse material, thereby cutting off the electrical connection.

It should be appreciated that evaporation may result in a huge expansion of the volume of the material. If the evaporated material is allowed to escape from the fuse region such as through a window opening, this can be harmless. However, if the fuse region is restrictive, the evaporated material may settle back and the fuse may become partially conductive again at a later time. Usually, a protective layer, referred to as a passivation layer, is provided on top of the IC to protect the IC from physical force and/or contamination. The passivation layer, if intact, can block the escape of the evaporated material. Also, there can be problems if trimming is attempted after device packaging

In order free an explosive gaseous compound, a window in the passivation layer may need to be opened. However, opening a window in the passivation layer can not only add to manufacturing process step count, but can also unfavorably provide an open path for mobile ions or other contaminations to enter the device. The space taken up when such a window is opened includes that occupied by the fuse structures and the bonding pads used to read and program the fuses.

As discussed above a Zener diode can be employed as a fuse in device trimming. By providing a considerable reverse voltage across the Zener diode, the Zener diode can break down which causes a current to flow through the Zener diode. Therefore, the resistance of the fuse is decreased. However, this solution involves a very demanding manufacturing process.

The use of Flash memory or EEPROM for trimming is ideal if the design of the IC otherwise requires the use of the memories. However, this is a very expensive way to provide trimming functionality. The reason is that the use of memory would increase process complexity and significantly increase the size of the chip.

Other trimming methods involve the cutting of a connection by action of a laser or other physical means. These methods may also need the opening of a physical window and tend to be more expensive to apply, and are not suitable for large scale production.

### SUMMARY OF THE INVENTION

The present invention advantageously provides a fuse circuit in a dielectric layer for trimming an Integrated Circuit (IC). The fuse circuit employs a single metal plug which is disposed in the dielectric layer as a trimming fuse. As a result, the goal of reducing the complexity and cost of IC manufacturing process and enhancing the reliability of the IC can be achieved.

For one embodiment of this invention, there is provided a fuse circuit in a dielectric layer for trimming an Integrated Circuit (IC). The fuse circuit has a first conductive layer, a second conductive layer, a third conductive layer, a first metal plug, and at least one metal plug. The first conductive layer and the second conductive layer are connected by the first metal plug. The first conductive layer and the third conductive layer are connected by the aforementioned at least one metal plug. Therefore, a first conductive path is formed between the second and the third conductive layers via the first metal plug, the first conductive layer and the at least one metal plug. The conductive path can be cut off by applying a predetermined current to the first conductive path to destroy the first metal plug.

In another embodiment of this invention, there is provided a method for providing a fuse circuit for trimming an Integrated Circuit (IC). The method includes the steps of forming a first conductive layer on the surface of a field oxide substrate, forming a dielectric layer on the first conductive layer, forming a first metal plug and at least one metal plug in the dielectric layer and forming a second conductive layer and a third conductive layer on the surface of the dielectric layer. In particular, the first metal plug is coupled between the first and second conductive layers. The at least one metal plug is coupled between the first and third conductive layers.

In yet another embodiment of the present invention there is provided an apparatus having metal plugs as trimming fuses. The apparatus includes an Integrated Circuit having a predefined function and a trimming unit coupled to the Integrated Circuit. The trimming unit has a first conductive layer, a second conductive layer, a third conductive layer, a first metal plug, and at least one metal plug. The first conductive layer and the second conductive layer are connected by the first metal plug. The first conductive layer and the third conductive layer are connected by the aforementioned at least one metal plug. Therefore, a first conductive path is formed between the second and the third conductive layers via the first metal plug, the first conductive layer and the at least one metal plug. In order to adjust a certain parameter of the Integrated Circuit, the first conductive path can be cut off by applying a predetermined current to the first conductive path to destroy the first metal plug.

### BRIEF DESCRIPTION OF THE DRWAINGS

Features and advantages of embodiments of the invention will become apparent as the following Detailed Description proceeds, and upon reference to the Drawings, where like numerals depict like elements, and in which:

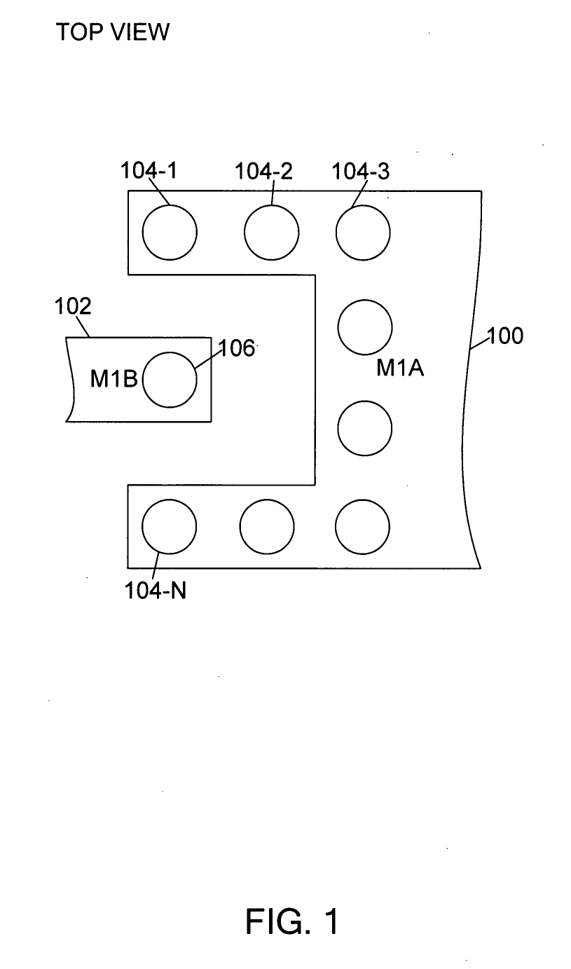

FIG. 1 illustrates a top view of a single stage W-plug fuse according to one embodiment of the present invention.

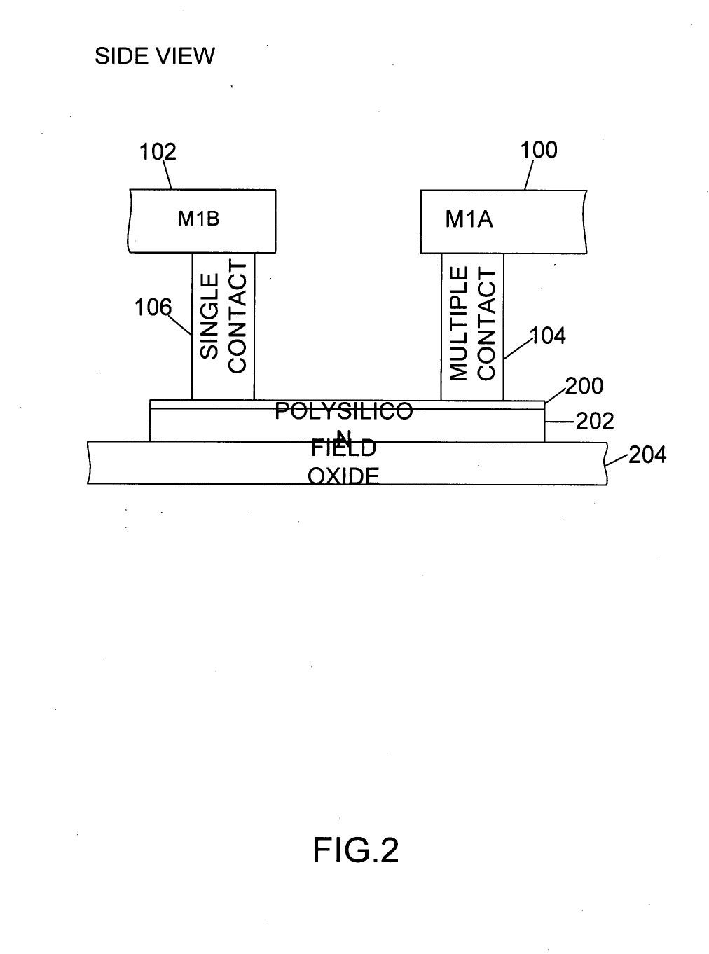

FIG. 2 illustrates a side view of a single stage W-plug fuse according to one embodiment of the present invention.

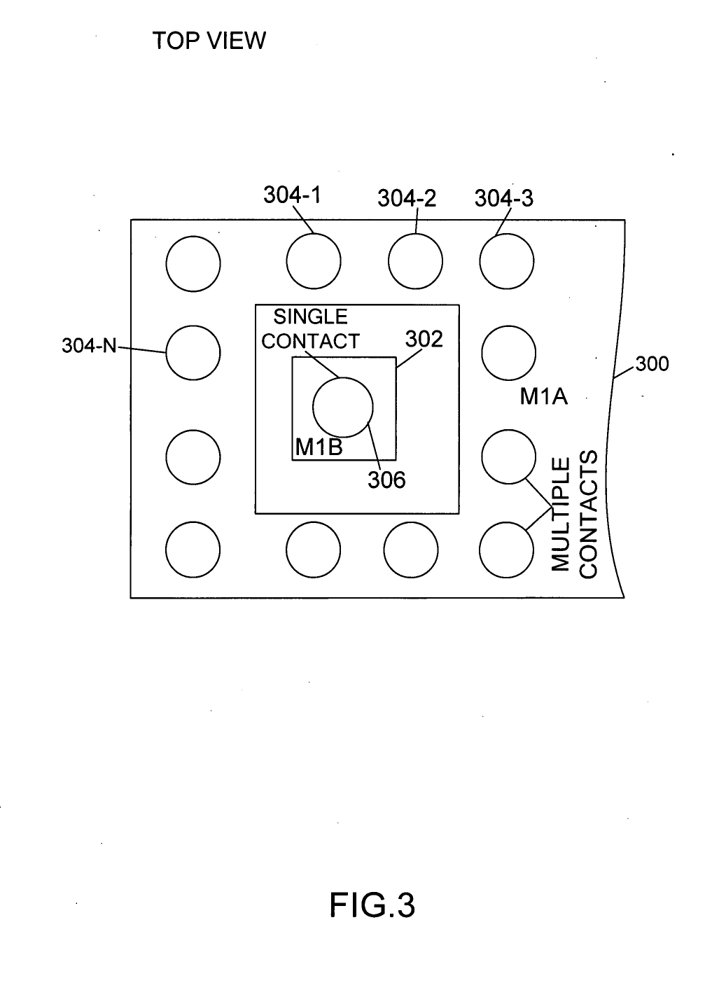

FIG. 3 illustrates a top view of a two stage W-plug fuse according to one embodiment of the present invention.

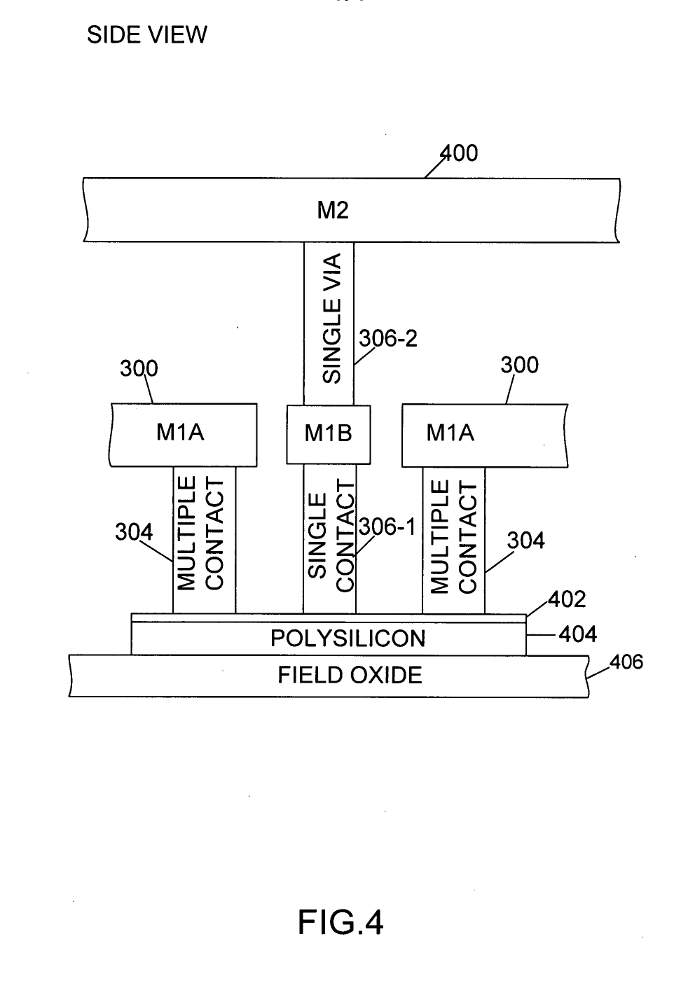

FIG. 4 illustrates a side view of a two stage W-plug fuse according to one embodiment of the present invention.

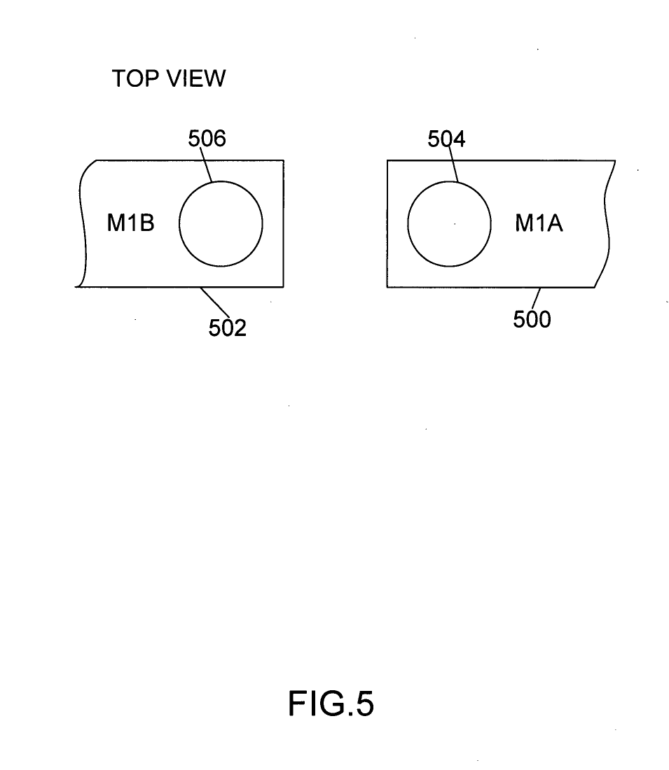

FIG. 5 illustrates a top view of yet another single stage W-plug according to one embodiment of the present invention.

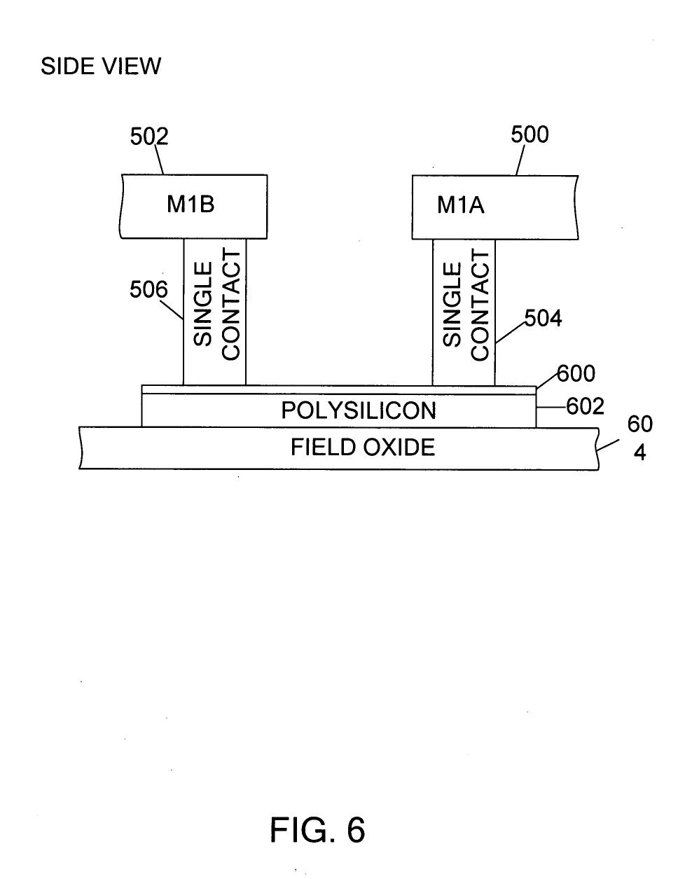

FIG. 6 illustrates a side view of yet another single stage W-plug according to one embodiment of the present invention.

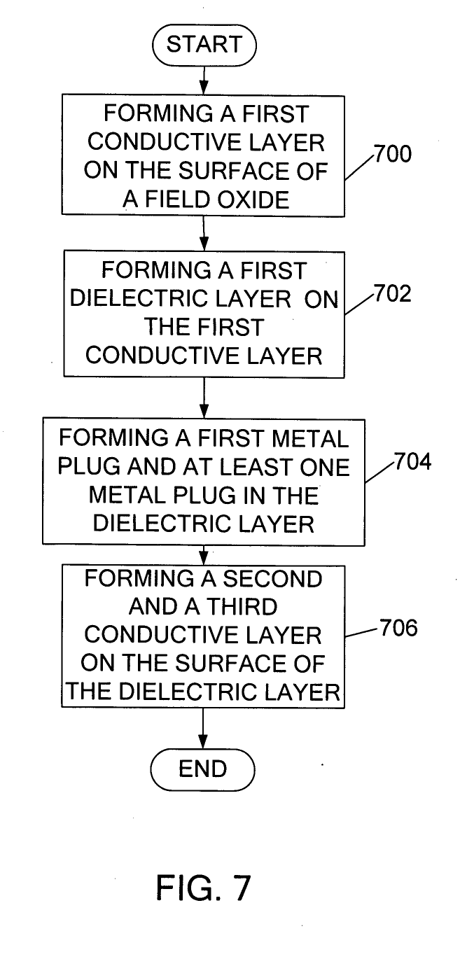

FIG. 7 illustrates a flow chart of a method for providing a fuse circuit for trimming an Integrated Circuit.

### DETAILED DESCRIPTION OF THE INVENTION

Tungsten plug (W-plug) technology has been used extensively in recent years in the interconnection between polysilicon and a first layer of metal (metal 1), or between metal layers. Contacts and vias are two forms of W-plug. Contacts and vias made of tungsten plugs are vertical in shape and take up a small space. These types of W-plugs are very stable and reliable ways to make interconnections. Tungsten has somewhat higher electrical resistivity as compared with aluminum. However, used in short distance interconnection that may not be a problem. It has the added advantage of improving electromigration performance that is a common problem with aluminum metallurgy.

Generally, in typical process to form W-plug contacts between polysilicon and metal 1, contact holes may need to be formed beforehand. The contact holes are formed by photolithography patterning process. The holes are etched into the insulating dielectric layers to stop on the poly or single crystal silicon below. The inside of the contact holes are cleaned by using plasma or solvent cleans. The barrier metal of collimated Ti and TiN are sputtered into the contact holes and on the wafer surface. The deposition of tungsten is done by chemical vapor deposition (CVD) in a process chamber at reduced pressure (a few torrs) and elevated temperature (about 400□). The initiation step uses SiH4+WF6 to deposit a thin layer of WSi on all the surfaces. Then the gas mixture is changed to H2+WF6 to deposit pure W to fill the contact holes. This is the so-called non-selective W process, where W is deposited on the top surface of the wafer and in the contact holes. The W on top of wafer is removed using anisotropic etch back process or by W-CMP (Chemical Mechanical Polish) to leave behind only W in the contact holes. After wafer clean, barrier metal and/or a layer of aluminum metal (metal 1) is sputtered onto the wafer. Metal 1 is patterned and etched to form the next layer of metal interconnection. The above-mentioned description is a fabricating process for process standard that is used for 0.8 μm or below IC device.

Similar process steps are used to form W-plug filled vias between metal 1 and metal 2.

The present invention makes use of the high resistivity characteristic of the tungsten plug and exploits the tungsten plug as a new type of fuse. By delivering a high pulse or continuous current of electrical energy through, the contact or via W-plug can be permanently destroyed and be rendered incapable of conducting electricity. This characteristic is similar to the concept of a fuse, which makes it possible to use a tungsten plug as a fuse. The idea of the present invention will become apparent as the following detailed description of the present invention proceeds.

FIG. 1 and FIG. 2 illustrate respectively a top view and a side view of a single stage fuse circuit disposed in a dielectric layer according to one embodiment of the present invention. A first conductive layer (M1A) 100 and a second conductive layer (M1B) 102 are provided as shown in FIG. 1 and FIG. 2. Generally, the first conductive layer M1A 100 and the second conductive layer M1B 102 may be metal layers such as aluminum layers or copper layers. As illustrated in FIG. 1, M1A 100 may have a plurality of W-plug contacts numbered consecutively from 104-1 to 104-N connected to it. M1B 102 has a first metal plug (W-plug contact or W-plug fuse) 106 connected to it. The W-plug contacts numbered consecutively from 104-1 to 104-N should be packed as closely to the W-plug fuse 106 as is allowed by design rule. As illustrated in FIG. 2 W-plug contacts 104-1-104-N and 106 are connected to a first conductive layer 202. In the present embodiment, the first conductive layer 202 is a slab of polysilicon. The top of the polysilicon 202 may have a layer of silicide 200 which is formed between silicon and tungsten, titanium, cobalt or other metal. The polysilicon slab 202 should be sufficiently large and sitting on top of a field oxide 204 to minimize any effect fuse burning may have on the single-crystal silicon or to the IC. It should be appreciated by those skilled in the art that, M1A 100 and M1B 102 are coupled by a first conductive path. The first conductive path is form by the W-plug contact 106, the first conductive layer 202 and W-plug contacts numbered consecutively from 104-1 to 104-N. In the course of trimming, M1A 100 and M1B 102 are separately connected to power source through bonding pads which are not shown herein.

As previously stated, W-plug contacts numbered consecutively from 104-1 to 104-N are packed as closely to the W-plug 106 as is allowed by design rule, therefore the resistance between the W-plug contact 106 and W-plugs contacts numbered consecutively from 104-1 to 104-N is as low as possible. Moreover, as W-plug contacts 104-1-104-N are coupled in parallel between M1A 100 and polysilicon 200, therefore total resistance introduced by the W-plug contacts 104-1-104-N is substantially lower than the resistance introduced by the W-plug contact 106. Consequently, in this circuit, the part with highest resistance is the W-plug contact 106. When power is applied (as a pulse or continuous current) between M1A 100 and M1B 102, the W-plug contact 106 can heat up. When enough electrical energy is delivered, the W-plug contact 106 can be destroyed and can result in a high resistance. Therefore, the first conductive path is cut off. It should be noted that W-plug contacts 104-1-104-N connected to M1A 100 may not be easily destroyed since the electrical energy delivered to each of the contact becomes divided and lessened.

Advantageously, the W-plug contact 106 described herein used as a fuse can be small in size compared with the conventional fuse structure. Furthermore, the W-plug contact 106 can be formed as an integral part of the manufacturing process flow so that no extra processing step is required. Unlike the poly fuse that would normally require an additional masking step to open a window on the passivation layer to allow the fuse to blow thoroughly, tungsten fuses do not require this additional masking step, which helps to reduce the number of masking steps. The trimming processing is done on top of the field oxide 204 and polysilicon 202 so that little damage is done to the single crystal silicon material upon which the device is built. Moreover, the fact that there is no hole in the passivation layer makes the device more reliable as there is no passage way for moisture and mobile ions to enter the IC. Also, in the process, if a poly fuse window is over-etched, the fuse may be damaged which, in turn, can create difficulty in burning the fuse. Advantageously, since the W-plug fuse is an integral part of the process flow, this type of processing problem is unlikely to occur.

Depending on the detailed process architecture that is employed, certain events can occur: (1) temperature can get so high instantaneously that tungsten and/or its surrounding silicon oxide can be melted, which can cause chemical reaction and/or distortion to the W-plug contact 106 and makes the tungsten become non-conductive. (2) The barrier metal may fail due to high temperature before the tungsten melting point is reached and become non-conductive.

It should be noted that in some other embodiments, the W-plug contacts 104-1-104-N and 106 may also be connected to the single-crystal silicon (instead of polysilicon) which may or may not be silicidized.

The fuse can also consist of more than one W-plug, which allows more freedom to design and utilize the device. FIG. 3 and FIG. 4 illustrate a top view and a side view respectively of a two stage fuse circuit according to one embodiment of the present invention. As illustrated in FIG. 3, a third conductive layer (M1A) 300 forms a ring around a single W-plug fuse 306. M1A 300 may have a plurality of W-plug contacts numbered consecutively from 304-1 to 304-N connected to it. The single W-plug fuse 306 of this embodiment consists of a first metal-plug (W-plug) 306-1 and a second metal plug (W-plug) 306-2 in the form of a contact and a via respectively. A second conductive layer (M1B) 302 is just a landing pad between the W-plug contact 306-1 and W-plug via 306-2. The W-plug via 306-2 is connected to a fourth conductive layer (M2) 400 which is connected to the trimming power source. The fourth conductive layer 400 may also be a metal layer. The W-plug contact 306-1 and the plurality of W-plug contacts numbered consecutively from 304-1 to 304-N are connected to a first conductive layer 404. The top layer of the first conductive layer 404 may also be conductive silicide. Herein the fourth conductive layer 400 is electrically connected to M1A 300 via a second conductive path. The second conductive path is formed by the second metal plug (W-plug via) 306-2, M1B 302, the W-plug contact 306-1, the first conductive layer 402 and the plurality of W-plug contacts numbered consecutively from 304-1 to 304-N. To reduce the resistance introduced by the fourth conductive layer M2 400, the fourth conductive layer M2 400 between the trimming power source and the W-plug via 306-2 should be as short as possible. Preferably, the single W-plug fuse 306 can be positioned directly underneath a bonding pad for burning.

It is appreciated by those skilled in the art that the pad may be able to position multiple fuses under it. It should also be noted that the concept of W-plug fuse can also be applied to other metals used in contact or via, such as Cu which is widely used in advanced processes, that involve 0.15 μm geometries and below. Furthermore, the use of W-plug fuse is not limited to one metal layer or two metal layers application as illustrated herein, but may also be applicable to any number of metal layers.

FIG. 5 and FIG. 6 illustrate a top view and a side view of yet another single stage W-plug according to one embodiment of the present invention. In this embodiment, M1A 500 has 1 W-plug contact 504, and M1B 502 has 1 W-plug 506. Therefore, W-plug contacts 504 and 506 are parts of the fuse, which can make the fuse a little easier to burn. However, a sensing circuitry (not shown) for detecting the state of the W-plug contacts 504 and 506 is needed, the description of which is similar to that of the FIG. 3 and FIG. 4 embodiment.

FIG. 7 illustrates an exemplary flow chart of a method for providing a fuse circuit for trimming an Integrated Circuit. To provide the fuse circuit, a first conductive layer can be formed on the surface of a field oxide substrate, step 700. The conductive layer maybe a conductive silicide layer which is grew on the top of a slab of polysilicon or single-crystal silicon. The silicide layer may be formed between silicon and tungsten, titanium, cobalt or other metal. Then, a dielectric layer can be formed on the surface of the first conductive layer, step 702. When the dielectric layer is ready, a first metal plug and at least one metal plug can be further formed in the dielectric layer, step 704. To accommodate the aforementioned metal plugs, contact holes must be formed beforehand. Generally, contact holes are formed by photolithography patterning process. Contact holes are etched into the dielectric layers to stop on the first conductive layer below. Before grow metal plugs in contact holes, the inside of the contact holes may be cleaned by using plasma or solvent cleans and then a layer of barrier metal can be sputtered into the contact holes. Once the barrier metal layer is ready, metal plugs can be deposed in contact holes by using the aforementioned non-selective W process. The metal plugs may be tungsten plugs or copper plugs. When the non-selective W process is finished, tungsten may also be formed on the surface of the dielectric layer. Thus, the surface of the dielectric layer may need to be cleaned by employing the aforementioned anisotropic etch back or CMP process. Then, a second conductive layer and a third conductive layer can be further formed on the surface of the dielectric layer, step 706. Particularly, the second conductive layer and the third conductive layer are electrically isolated by the dielectric layer. The second conductive layer connects to the first metal plug. The third conductive layer connects to the aforementioned at least one metal plug. Therefore, the second conductive layer and the third conductive layer are electrically connected by an electric connection provided by the first metal plug, the first conductive layer, the at least one metal plug. It should be noted that a certain parameter of the IC can be adjusted by cutting off the electric connection in a latter trimming process. In the latter trimming process, the electric connection can be cut off by applying a predetermined current to destroy the first metal plug.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Other modifications, variations, and alternatives are also possible. Accordingly, the claims are intended to cover all such equivalents.

What is claimed is:

1. A fuse circuit in a dielectric layer for trimming an Integrated Circuit (IC), comprising:
a first conductive layer;
a second conductive layer;
a third conductive layer;
a first metal plug coupled between said first and second conductive layers; and
at least one metal plug coupled between said first and said third conductive layers, wherein a first conductive path is formed between said second conductive layer and said third conductive layer via said first metal plug, said first conductive layer and said at least one metal plug, and said conductive path can be cut off by applying a predetermined current to said first conductive path to destroy said first metal plug.

2. The fuse circuit of claim 1, wherein said first conductive layer is a conductive silicide layer.

3. The fuse circuit of claim 1, wherein said second and third conductive layers are metal layers.

4. The fuse circuit of claim 1, wherein said first metal plug and said at least one metal plugs are tungsten plugs.

5. The fuse circuit of claim 1, further comprising:
a fourth conductive layer;
a second metal plug coupled between said second conductive layer and said fourth conductive layer, wherein a second conductive path is formed between said fourth conductive layer and said third conductive layer via said second metal plug and said first conductive path.

6. The circuit of claim 5, wherein said second conductive path can be cut off by applying a predetermined current to destroy said second metal plug.

7. The circuit of claim 5, wherein said fourth conductive layer is a metal layer.

8. The current of claim 5, wherein said second metal plug is a tungsten plug.

9. A method for providing a fuse circuit for trimming an Integrated Circuit (IC), comprising:
forming a first conductive layer on the surface of a field oxide substrate;
forming a dielectric layer on said first conductive layer;
forming a first metal plug and at least one metal plug in said dielectric layer; and
forming a second and a third conductive layer on the surface of said dielectric layer, said first metal plug being coupled between said first conductive layer and said second conductive layer, said at least one metal plug being coupled between said first conductive layer and said third conductive layer.

10. The method of claim 9, wherein said first conductive layer is a layer of conductive silicide produced on a slab of silicon.

11. The method of claim 9, wherein said second and third conductive layers are metal layers that are electrically isolated by said dielectric layer.

12. The method of claim 9, wherein said first metal plug and said at least one metal plugs are tungsten plugs.

13. The method of claim 9, further comprising:
applying a predetermined current to destroy said first metal plug when a parameter of said IC needs to be adjusted.

14. The method of claim 13, wherein said second and third conductive layers are electrically connected by an electrical connection provided by said first metal plug, said first conductive layer and said at least one metal plug.

15. An apparatus having metal plugs as trimming fuses, comprising:
an Integrated Circuit having a predefined function; and
a trimming unit coupled to said Integrated Circuit, said trimming unit being capable of adjusting a parameter of said Integrated Circuit, said trimming circuit comprising:
a layer conductive layer;
a second conductive layer;
a third conductive layer;
a first metal plug coupled between said first and second conductive layers; and
at least one metal plug coupled between said first and third conductive layers, wherein a first conductive path is formed between said second conductive layer and said third conductive layer via said first metal plug, said first conductive layer and said at least one metal plug, and said parameter can be adjusted by providing a predetermined current to cut off said first conductive path.

16. The apparatus of claim 15, wherein said conductive path is cut off by using said predetermined current to destroy said first metal plug.

17. The apparatus of claim 15, wherein said first metal plug and said at least one metal plugs are tungsten metal plugs.

18. The apparatus of claim 15, wherein said first conductive layer is a conductive silicide layer.

19. The apparatus of claim 15, wherein said second and third layers are metal layers.

20. The apparatus of claim 15, wherein said trimming circuit further comprises:
a fourth conductive layer;
a second metal plug coupled between said second conductive layer and said fourth conductive layer, wherein a second conductive path is formed between said fourth conductive layer and said third conductive layer via said second metal plug and said first conductive path.
